(19) United States
(12) Patent Application Publication
(10) Pub. No.: US 2011/0081618 A1
(43) Pub. Date: Apr. 7, 2011

(54) LITHO-LITHO ETCH (LLE) DOUBLE PATTERNING METHODS

(75) Inventors: Yi-Ming Wang, Taoyuan County (TW); Pei-Lin Huang, Taoyuan County (TW); Ying-Chung Tseng, Taoyuan County (TW)

(73) Assignee: NANYA TECHNOLOGY CORPORATION, Taoyuan (TW)

(21) Appl. No.: 12/574,650

(22) Filed: Oct. 6, 2009

(51) Int. Cl. G03F 7/20

(52) U.S. Cl. 430/325

(57) ABSTRACT

Litho-litho-etch double patterning (LLE-DP) methods using silylation freeze technology are presented. The LLE-DP method using a silylation freeze reaction comprises providing a substrate with a first photoresist layer thereon. A first exposure process is performed defining a first latent image in a first photoresist. The first patterned structures on the substrate is developed and baked for photo-generated acid diffusion. The photo-generated acid is reacted with a silylation agent to freeze the first patterned structures. A second photoresist layer is formed overlying the substrate. A second lithography process is performed to create second patterned structures on the substrate. The first patterned structures and the second patterned structures are interlaced each other.

### BACKGROUND OF THE INVENTION

1. Field of the Invention

The invention relates to advanced lithography methods, and in particular, to litho-litho-etch double patterning (LLE-DP) methods using silylation freeze technology.

2. Description of the Related Art

Advanced lithography methods have been disclosed, including an optical lithography, photoresists, metrology, Extreme Ultraviolet (EUV), immersion, double patterning and imprint lithography method.

Double patterning (DP) lithography is used for 32 nm node manufacturing. Litho-Litho-Etch DP lithography, one type of DP lithography method, has low cost-of-ownership when compared to the Litho-Etch-Litho-Etch DP lithography method. However, Litho-Litho-Etch DP lithography uses novel materials and processes that have not been fully characterized. Litho-Litho-Etch (LLE) double patterning processes without intermediate processing steps have been disclosed to achieve narrow pitch photoresist imaging. One type of LLE double patterning (LLE-DP) process, combines positive tone-negative tone and positive tone-positive tone photoresist double patterning processes. However, the LLE double patterning process is not feasibly used for 32 nm node manufacturing.

U.S. Pat. No. 6,280,908, the entirety of which is hereby incorporated by reference, discloses a post-development photoresist hardening method by vapor silylation. A hardened resist surface is obtained to etch at a slower rate than that of untreated resist surfaces.

FIGS. 1A-1E are cross sections illustrating each step of the conventional LLE-DP method. Referring to FIG. 1A, a substrate 110 is provided with a layer 110 of material thereon. First patterned structures 115a are formed on the material layer 110. A frozen material layer 120 is coated on the substrate 100 covering the first patterned structures 115a. The frozen material layer 120 is subsequently baked, thereby stiffening the frozen first patterned structures 115 and subsequently removed from the substrate 100, as shown in FIG. 1C. Referring to FIG. 1E, a photoresist layer 130 is formed overlying the substrate 110 covering the frozen first patterned structures 115. A lithography process is performed to create second patterned structures 135. In order to prevent the first patterned structure from damage, the frozen material layer 120 is used to stiffen the first patterned structure. However, processes of coating, baking and developing the frozen material layer 120 are complex, tedious and expensive.

### BRIEF SUMMARY OF THE INVENTION

An embodiment of the invention provides a litho-litho-etch double patterning (LLE-DP) method using a silylation freeze reaction, comprising: providing a substrate with a first photoresist layer thereon; performing a first lithography process to create first patterned structures; performing a silylation freeze reaction on the first patterned structures; forming a second photoresist layer overlying the substrate; and performing a second lithography process to create second patterned structures.

Another embodiment of the invention provides a litho-litho-etch double patterning method using a silylation freeze reaction, comprising: providing a substrate with a first photoresist layer thereon; performing a first lithography process to create first patterned structures on the substrate; reacting a photo-generated acid with a silylation agent to freeze the first patterned structures; forming a second photoresist layer overlying the substrate; and performing a second lithography process to create second patterned structures.

Another embodiment of the invention provides a litho-litho-etch double patterning method using a silylation freeze reaction, comprising: providing a substrate with a first photoresist layer thereon; performing a first exposure process defining a latent image in a first photoresist; developing and baking the first patterned structures for photo-generated acid diffusion; reacting a photo-generated acid with a vapor phase silylation agent to freeze the first patterned structures; forming a second photoresist layer overlying the substrate; and performing a second lithography process to create second patterned structures.

### BRIEF DESCRIPTION OF THE DRAWINGS

The invention can be more fully understood by reading the subsequent detailed description and examples with references made to the accompanying drawings, wherein:

FIGS. 1A-1E are cross sections illustrating each step of a conventional litho-litho-etch double patterning (LLE-DP) method;

FIG. 2 is a flowchart of an exemplary embodiment of the litho-litho-etch double patterning method using silylation freeze technology;

FIGS. 3A-3F are cross sections illustrating each step of an exemplary embodiment of the litho-litho-etch double patterning method using silylation freeze technology; and

FIG. 4 is a schematic view illustrating a silylation mechanism of embodiments of the invention.

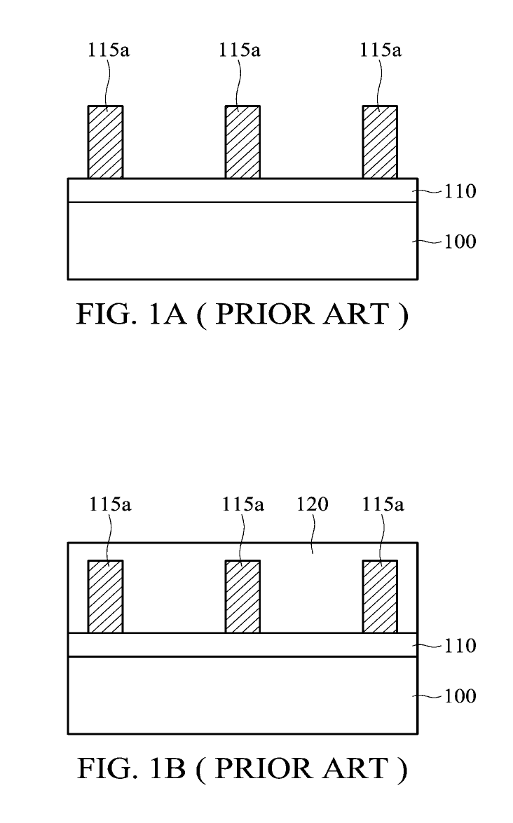

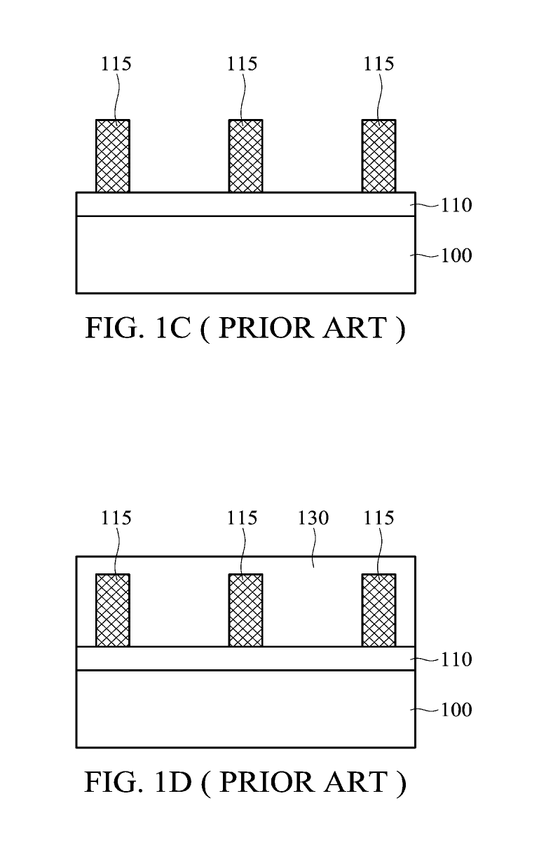

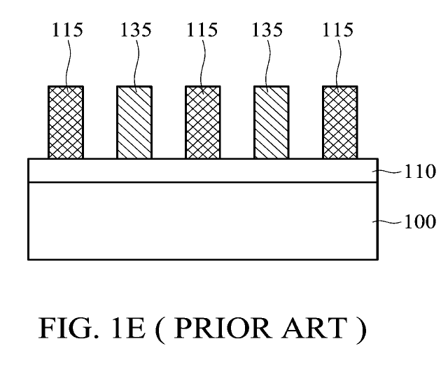

### DETAILED DESCRIPTION OF THE INVENTION

It is to be understood that the following disclosure provides many different embodiments, or examples, for implementing different features of various embodiments. Specific examples of components and arrangements are described below to simplify the present disclosure. These are merely examples and are not intended to be limiting. In addition, the present disclosure may repeat reference numerals and/or letters in the various examples. This repetition is for the purpose of simplicity and clarity and does not in itself indicate a relationship between the various embodiments and/or configurations discussed. Moreover, the formation of a first feature over or on a second feature in the description that follows may include embodiments in which the first and second features are formed in direct contact or not in direct contact.

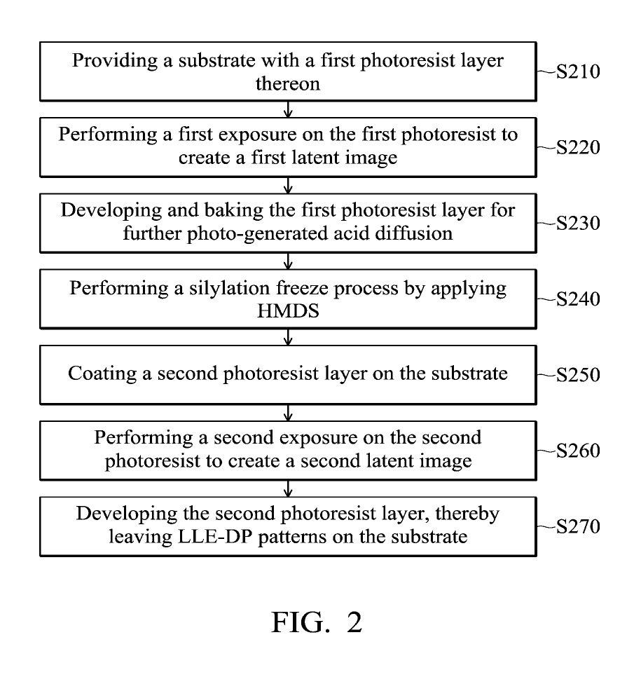

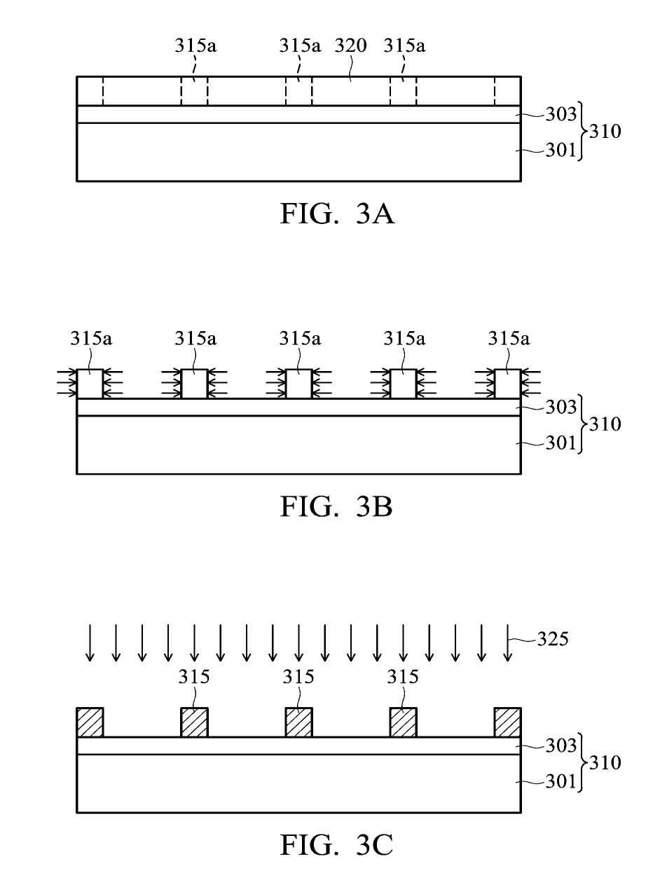

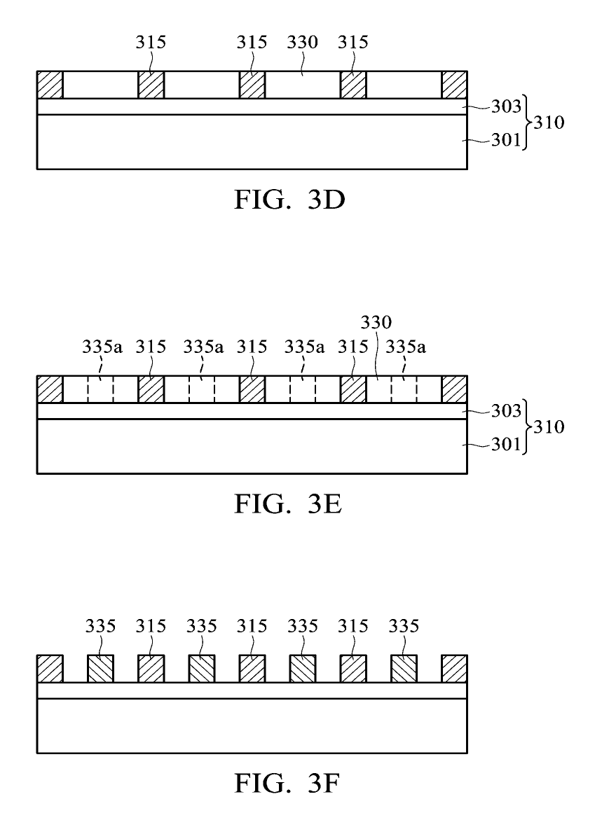

Embodiments of the invention provide a litho-litho-etch double patterning (LLE-DP) method using silylation freeze technology. FIG. 2 is a flowchart of an exemplary embodiment of the litho-litho-etch double patterning method using silylation freeze technology. FIGS. 3A-3F are cross sections illustrating each step of an exemplary embodiment of the litho-litho-etch double patterning method using silylation freeze technology.

The litho-litho-etch double patterning method begins with step S210, in which a substrate is provided with a first photoresist layer thereon. Referring to FIG. 3A, a substrate 310 includes a silicon substrate (e.g., wafer) 301 and a layer of material 303 thereon. The substrate 310 may include various doping configurations depending on design requirements as known in the art. The substrate 310 may also include other semiconductor substrates, epitaxial substrates, SiGe strained substrates, and silicon on insulator (SOI) substrates. A first photoresist 320 is formed on the substrate 310.

In step S220, a first exposure procedure is performed on the first photoresist to create a first latent image. Referring to FIG. 3A, the first photoresist 320 with a first latent image 315a therein may be formed by a photo lithography or other suitable process.

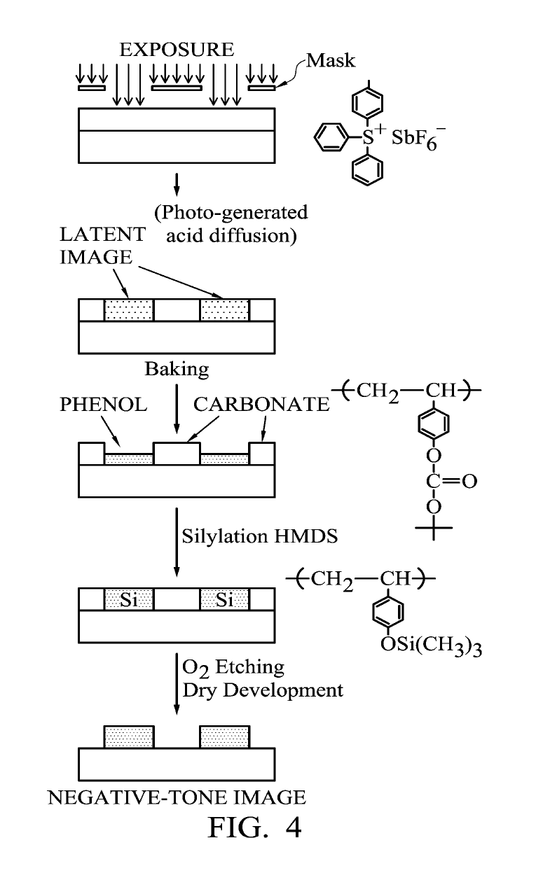

In step S230, the first photoresist layer is developed and baked for photo-generated acid diffusion. The exposed photoresist layer includes photo-generated acid dispersed therein. Referring to FIG. 3B, the first patterned structure 315a is developed and baked for photo-generated acid diffusion as indicated by the lateral arrows. Subsequently, in step S240, a silylation freeze process is performed by applying hexamethyldisilazane (HMDS). Referring to FIG. 3C, a silylation freeze process 325 comprises reacting a silylation agent with the photo-generated acid to freeze the first patterned structure 315. In one embodiment, the silylation agent may comprise hexamethyldisilazane, trimethylchlorosilane (TMCS), hexamethyldisilazane (HMDSZ), or other suitable silylation agent. The silylation agent can be in liquid phase or in vapor phase or in both liquid and vapor phase. According to some embodiments of the invention, the exposed photoresist layer with latent image includes photo-generated acid dispersed in the photoresist. The developed and baked photoresist is exposed to a liquid phase or vapor phase or both liquid and vapor phase of a silylation agent. During silylation with HMDS, the phenolic groups are converted to corresponding trimethylsilyloxy groups, as shown in FIG. 4. Oxygen plasma etching of the silylation film then provides a negative-tone image.

In step S250, a second photoresist layer is coated on the substrate. In FIG. 3D, a second photoresist layer 330 is formed on the substrate 310. Subsequently, in step S260, a second exposure is performed on the second photoresist to create a second latent image. In FIG. 3E, the second photoresist 330 with a second latent image 335a therein may be formed by photo lithography or other suitable processes.

In step S270, the second photoresist layer is developed and baked, thereby leaving LLE-DP patterns on the substrate. In FIG. 3F, the first patterned structures 315 and the second patterned structures 335 are interlaced each other. For example, the ratio of the width of the first patterned structures 315 to the interval distance is 1:3, and the ratio of the width of the second patterned structures 335 to the interval distance is 1:3. Therefore, the first patterned structures 315 and the second patterned structures 335 are interlaced each other with the same interval.

The LLE-DP methods using silylation freeze reaction are advantageous in that photoresist materials for dry development after the silylation process are readily available. The LLE-DP methods can be compatible with well-developed lithography processes including mask-making, exposure, wet development, and dry development processes.

While the invention has been described by way of example and in terms of the preferred embodiments, it is to be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A litho-litho-etch double patterning (LLE-DP) method using a silylation freeze reaction, comprising:
providing a substrate with a first photoresist layer thereon;
performing a first lithography process to create first patterned structures on the substrate;
performing a silylation freeze reaction on the first patterned structures;
forming a second photoresist layer overlying the substrate; and
performing a second lithography process to create second patterned structures on the substrate.

2. The LLE-DP method as claimed in claim 1, wherein the substrate comprises a single crystalline structure, an epitaxial substrate, a SiGe substrate, and a silicon on insulator (SOI) substrate.

3. The LLE-DP method as claimed in claim 1, wherein the step of performing the first lithography process comprises:
performing an exposure process defining a first latent image in the first photoresist; and
developing and baking the first patterned structures for photo-generated acid diffusion.

4. The LLE-DP method as claimed in claim 1, wherein the step of performing the silylation freeze process comprises reacting a silylation agent with the photo-generated acid.

5. The LLE-DP method as claimed in claim 4, wherein the silylation agent comprises hexamethyldisilazane (HMDS), trimethylchlorosilane (TMCS), or hexamethyldisilazane (HMDSZ).

6. The LLE-DP method as claimed in claim 1, wherein the step of performing the second lithography process comprises:
performing an exposure process defining a second latent image in the second photoresist; and
developing and baking the second photoresist layer to create the second patterned structures.

7. The LLE-DP method as claimed in claim 1, wherein the first patterned structures and the second patterned structures are interlaced each other.

8. A litho-litho-etch double patterning (LLE-DP) method using a silylation freeze reaction, comprising:
providing a substrate with a first photoresist layer thereon;
performing a first lithography process to create first patterned structures on the substrate;
reacting a photo-generated acid with a silylation agent to freeze the first patterned structures;
forming a second photoresist layer overlying the substrate; and
performing a second lithography process to create second patterned structures on the substrate.

9. The LLE-DP method as claimed in claim 8, wherein the substrate comprises a single crystalline structure, an epitaxial substrate, a SiGe substrate, and a silicon on insulator (SOI) substrate.

10. The LLE-DP method as claimed in claim 8, wherein the step of performing the first lithography process comprises:
performing an exposure process defining a first latent image in the first photoresist; and
developing and baking the first patterned structures for photo-generated acid diffusion.

11. The LLE-DP method as claimed in claim 8, wherein the silylation agent comprises hexamethyldisilazane (HMDS), trimethylchlorosilane (TMCS), or hexamethyldisilazane (HMDSZ).

12. The LLE-DP method as claimed in claim 8, wherein the step of performing the second lithography process comprises:
performing an exposure process defining a second latent image in the second photoresist; and
developing and baking the second photoresist layer to create the second patterned structures.

13. The LLE-DP method as claimed in claim 8, wherein the first patterned structures and the second patterned structures are interlaced each other.

14. A litho-litho-etch double patterning (LLE-DP) method using a silylation freeze reaction, comprising:
providing a substrate with a first photoresist layer thereon;
performing a first exposure process defining a first latent image in a first photoresist;
developing and baking the first patterned structures on the substrate for photo-generated acid diffusion;
reacting a photo-generated acid with a vapor phase silylation agent to freeze the first patterned structures;
forming a second photoresist layer overlying the substrate; and
performing a second lithography process to create second patterned structures on the substrate.

15. The LLE-DP method as claimed in claim 14, wherein the substrate comprises a single crystalline structure, an epitaxial substrate, a SiGe substrate, and a silicon on insulator (SOI) substrate.

16. The LLE-DP method as claimed in claim 14, wherein the vapor phase silylation agent comprises hexamethyldisilazane (HMDS), trimethylchlorosilane (TMCS), or hexamethyldisilazane (HMDSZ).

17. The LLE-DP method as claimed in claim 14, wherein the step of performing the second lithography process comprises:
performing a second exposure process defining a second latent image in the second photoresist; and
developing and baking the second photoresist layer to create the second patterned structures.

18. The LLE-DP method as claimed in claim 14, wherein the first patterned structures and the second patterned structures are interlaced each other.
